(19) United States
(12) Patent Application Publication
(10) Pub. No.: US 2012/0097206 A1
(43) Pub. Date: Apr. 26, 2012

(54) THERMOELECTRIC CONVERSION MODULE AND THERMOELECTRIC CONVERSION ELEMENT

(75) Inventors: Kazuo Sadaoka, Osaka (JP); Yoshinari Sawabe, Ibaraki (JP); Yuichi Hiroyama, Ibaraki (JP)

(73) Assignee: SUMITOMO CHEMICAL COMPANY, LIMITED, Chuo-ku, Tokyo (JP)

(21) Appl. No.: 13/123,006

(22) PCT Filed: Oct. 5, 2009
(86) PCT No.: PCT/JP2009/067593

§ 371 Date: May 16, 2011

(30) Foreign Application Priority Data
Oct. 7, 2008 (JP) 2008-260400

(51) Int. Cl. H01L 35/04

(52) U.S. Cl. 136/212

(57) ABSTRACT

The invention provides a thermoelectric conversion module and a thermoelectric conversion element. The thermoelectric conversion module comprises a plurality of thermoelectric conversion elements and a plurality of electrodes, wherein each of the thermoelectric conversion elements is made of a sintered body containing a thermoelectric conversion material and a conductive metal, has two faces, and satisfies the following condition (a) or (b): (a) each thermoelectric conversion element is electrically connected to an electrode via one face without a joint and is electrically connected to another electrode via the other face with a joint, (b) each thermoelectric conversion element is electrically connected to an electrode via one face without a joint and is electrically connected to another electrode via the other face without a joint.

### TECHNICAL FIELD

The present invention relates to a thermoelectric conversion module and to a thermoelectric conversion element.

### BACKGROUND ART

Thermoelectric conversion power generation is a type of electric power generation by method in which thermal energy is converted to electrical energy. In thermoelectric conversion power generation, electricity is generated by thermoelectromotive force produced by applying a temperature difference in the thermoelectric conversion element of the thermoelectric conversion module. Since heat generated geothermally or waste heat from an incinerator can be used as thermal energy, thermoelectric conversion power generation is expected as an environmentally friendly form of electric power generation. A thermoelectric conversion module normally has p-type thermoelectric conversion elements and n-type thermoelectric conversion elements electrically connected in series via electrodes, with the thermoelectric conversion elements being joined to the electrodes using a jointing material (solder) (JP 2004-342879A, for example).

### DISCLOSURE OF THE INVENTION

However, the thermoelectric conversion module above produces large thermal stress between the thermoelectric conversion element and the electrode during electric power generation, and therefore joining layers made of the jointing material get broken when thermal cycles have been carried out repeatedly. It is an object of the invention to provide a thermoelectric conversion module that can suppress thermal stress produced between the thermoelectric conversion element and electrode, and a thermoelectric conversion element favorable for the module.

The present invention has been completed as a result of much diligent research by the present inventors. Specifically, the invention provides the following, <1> to <19>.

<1> A thermoelectric conversion module comprising a plurality of thermoelectric conversion elements and a plurality of electrodes, wherein each of the thermoelectric conversion elements is made of a sintered body containing a thermoelectric conversion material and a conductive metal, has two faces, and satisfies the following condition (a) or (b):
(a) each thermoelectric conversion element is electrically connected to an electrode via one face without a joint, and is electrically connected to another electrode via the other face with a joint;
(b) each thermoelectric conversion element is electrically connected to an electrode via one face without a joint, and is electrically connected to another electrode via the other face without a joint.
<2> The module according to <1>, wherein the sintered body is a multilayer body comprising a first layer and a second layer, wherein the first layer is electrically connected to an electrode without a joint and contains a thermoelectric conversion material and a conductive metal,
the second layer is electrically connected to the first layer with a joint and contains a thermoelectric conversion material and a conductive metal, and
the ratio (molar ratio) of the conductive metal relative to the total amount (moles) of the thermoelectric conversion material and the conductive metal in the first layer is larger than the ratio (molar ratio) of the conductive metal relative to the total amount (moles) of the thermoelectric conversion material and the conductive metal in the second layer.
<3> The module according to <1> or <2>, wherein the sintered body has a columnar shape.
<4> The module according to any one of <1> to <3>, wherein the conductive metal is Ag.
<5> The module according to any one of <1> to <4>, wherein the thermoelectric conversion material is an oxide.
<6> The module according to <5>, wherein the oxide has a perovskite-type crystal structure or a layered perovskite-type crystal structure.
<7> The module according to any one of <1> to <6>, wherein the oxide contains manganese.
<8> The module according to <7>, wherein the oxide further contains calcium.
<9> The module according to any one of <2> to <8>, wherein the ratio (molar ratio) of the conductive metal relative to the total amount (moles) of the thermoelectric conversion material and conductive metal in the first layer is 0.1 or greater.
<10> The module according to any one of <1> to <9>, wherein the sintered body further contains copper oxide.
<11> A thermoelectric conversion element comprising a multilayer sintered body that comprises a first layer and a second layer, wherein the first layer is present on one end of the sintered body and contains a thermoelectric conversion material and a conductive metal, the second layer is electrically connected to the first layer with a joint and contains a thermoelectric conversion material and a conductive metal, and
the ratio (molar ratio) of the conductive metal relative to the total amount (moles) of the thermoelectric conversion material and the conductive metal in the first layer is larger than the ratio (molar ratio) of the conductive metal relative to the total amount (moles) of the thermoelectric conversion material and the conductive metal in the second layer.
<12> The element according to <11>, wherein the sintered body has a columnar shape.
<13> The element according to <11> or <12>, wherein the conductive metal is Ag.
<14> The element according to any one of <11> to <13>, wherein the thermoelectric conversion material is an oxide.
<15> The element according to <14>, wherein the oxide has a perovskite-type crystal structure or a layered perovskite-type crystal structure.
<16> The element according to any one of <11> to <15>, wherein the oxide contains manganese.
<17> The element according to <16>, wherein the oxide further contains calcium.
<18> The element according to any one of <11> to <17>, wherein the ratio (molar ratio) of the conductive metal relative to the total amount (moles) of the thermoelectric conversion material and conductive metal in the first layer is 0.1 or greater.
<19> The element according to any one of <11> to <18>, wherein the sintered body further contains copper oxide.

### BRIEF DESCRIPTION OF THE DRAWINGS

FIG. 1 is a schematic cross-sectional view showing an example of a thermoelectric conversion element.

FIG. 2 is a schematic cross-sectional view showing an example of a thermoelectric conversion element.

FIG. 3 is a schematic cross-sectional view showing an example of a thermoelectric conversion element.

FIG. 4 is a schematic cross-sectional view showing an example of a thermoelectric conversion module.

FIG. 5 is a schematic cross-sectional view showing an example of a thermoelectric conversion module.

FIG. 6 is a diagram showing a mode of use of a thermoelectric conversion module.

FIG. 7 is a schematic cross-sectional view showing an example of a thermoelectric conversion module.

FIG. 8 is a schematic cross-sectional view showing an example of a thermoelectric conversion module.

FIG. 9 is a diagram schematically illustrating a mode of use of a cap-shaped element support. In FIG. 9, (a) is a schematic view from the side, and (b) is a schematic view from the top.

### EXPLANATION OF SYMBOLS

10 Substrate
11 Higher-temperature side
12 Lower-temperature side
20 Electrode
30 Thermoelectric conversion element
31 p-Type thermoelectric conversion element
32 n-Type thermoelectric conversion element
40 Jointing material
50 Spring
60 Element support
61 Cap-shaped element support

### BEST MODE FOR CARRYING OUT THE INVENTION

### Thermoelectric Conversion Module

A thermoelectric conversion module comprises a thermoelectric conversion element and an electrode, and normally comprises a plurality of thermoelectric conversion elements and a plurality of electrodes. A thermoelectric conversion module also usually has thermoelectric conversion elements (p-type thermoelectric conversion elements and n-type thermoelectric conversion elements), electrodes, and optional members (substrates, supports, springs, and the like).

### Thermoelectric Conversion Element

The thermoelectric conversion element is made of a sintered body containing a thermoelectric conversion material and a conductive metal.

### [Thermoelectric Conversion Material]

It is preferable that the thermoelectric conversion material be, for example, an oxide thermoelectric conversion material, from the viewpoint of allowing it to withstand use at high temperatures of 600° C. and above. Examples of the oxide thermoelectric conversion material include NaCo₂O₄, Ca₃Co₄O₉, Li-doped NiO, ACuO_{2+δ} (where A is at least one selected from among Y, alkaline earth metal elements and rare earth metal elements, and δ is 0 or greater and 1 or smaller), RBa₂Cu₃O_{7-δ} (where R is at least one selected from among Y, Ce, Nd, Pm, Sm, Eu, Gd, Tb, Dy, Ho, Er, Tm, Yb and Lu, and δ is 0 or greater and 1 or smaller), (Ca, Sr)₁₄Cu₂₄O₄₁, delafossite compounds, (La, Sr)₂ZnO₄, LaCoO₃, SrFeO₃, SrTiO₃, LaNiO₃, Laₙ₊₁NiₙO₃ₙ₊₁ (where n is an integer of 1 to 10), manganese-containing oxides, Al-doped ZnO, (ZnO)ₘIn₂O₃ (where m is an integer of 1 to 19), (ZnO)ₘInGaO₃ (where m is an integer of 1 to 19), AeₓTi₈O₁₆ (where Ae is an alkaline earth metal, and x is 0.8 or greater and 2 or smaller) or Ti₁₋ₓMₓO_{y} (where M is at least one selected from the group consisting of V, Nb and Ta, x is 0.05 or greater and 0.5 or smaller, and y is 1.90 or greater and 2.02 or smaller). The oxide thermoelectric conversion material preferably has a perovskite-type crystal structure or a layered perovskite-type crystal structure among these materials, and specifically, the examples thereof include LaCoO₃, SrFeO₃, SrTiO₃, LaNiO₃ and Laₙ₊₁NiₙO₃ₙ₊₁ (where n is an integer of 1 to 10).

The oxide thermoelectric conversion material is preferably a manganese-containing oxide, and specifically an oxide represented by EMnO₃ (where E is at least one selected from the group consisting of Ca, Sr, Ba, La, Y and lanthanoids), Caₙ₊₁MnₙO₃ₙ₊₁ (where n is an integer of 1 to 10), CaMn₇O₁₂, Mn₃O₄, MnO₂ or CuMnO₂, and is more preferably a manganese-containing oxide containing calcium. The manganese-containing oxide preferably has a perovskite-type crystal structure or a layered perovskite-type crystal structure, from the viewpoint of further enhancing the thermoelectric conversion properties, as a thermoelectric conversion material.

Examples of manganese-containing oxides having a perovskite-type crystal structure include, specifically, oxides represented by CaMnO₃ (where a portion of Ca and/or Mn is optionally substituted with a different element). The examples of the different elements for substitution of a portion of Ca include one or more selected from among Mg, Sr, Ba, Sc, Y, La, Ce, Pr, Nd, Sm, Eu, Gd, Tb, Dy, Ho, Er, Tm, Yb, Lu, Bi, Sn, In and Pb, and is more preferably one or more selected from among Mg, Sr and Ba. The examples of the different elements for substitution of a portion of Mn include one or more selected from among V, Ru, Nb, Mo, W and Ta. Substituting a different element for a portion of Ca and/or Mn of the oxide represented by CaMnO₃ as mentioned above can further enhance thermoelectric conversion properties of the thermoelectric conversion element in some cases. Examples of manganese-containing oxides having a layered perovskite-type crystal structure include, specifically, oxides represented by formula (I):

Caₙ₊₁MnₙO₃ₙ₊₁ (1)

Where, n is an integer of 1 to 10, and a portion of Ca and/or Mn is optionally substituted with a different element.

The examples of the different elements for substitution of a portion of Ca in formula (I) include one or more selected from among Mg, Sr, Ba, Sc, Y, La, Ce, Pr, Nd, Sm, Eu, Gd, Tb, Dy, Ho, Er, Tm, Yb, Lu, Bi, Sn, In and Pb, and is more preferably one or more selected from among Mg, Sr and Ba. The examples of the different elements for substitution of a portion of Mn include one or more selected from among V, Ru, Nb, Mo, W and Ta. Substituting a different element for a portion of Ca and/or Mn of the oxide represented by formula (I) as mentioned above can further enhance thermoelectric conversion properties of the thermoelectric conversion element in some cases.

In addition, alloy-based thermoelectric conversion materials and non-oxide ceramic-based thermoelectric conversion materials may be used as thermoelectric conversion materials other than the above described oxide thermoelectric conversion materials. The examples of the alloy-based thermoelectric conversion materials include silicides, such as Mg₂Si, MnSi_{1.73}, Fe₁₋ₓMnₓSi₂, Fe₁₋ₓCoₓSi₂, Si_{0.8}Ge_{0.2} and β-FeSi₂, skutterudites, such as CoSb₃, FeSb₃ and RFe₃CoSb₁₂ (where R represents La, Ce or Yb), half-Heusler alloys, clathrate compounds, such as Ba₈Al₁₂Si₃₀ and Ba₈Al₁₂Ge₃₀, Te-containing alloys, such as BiTeSb, PbTeSb, Bi₂Te₃ and PbTe and other alloys, such as Zn₄Sb₃ and CoSb₃, and the examples of the non-oxide ceramic-based thermoelectric conversion materials include borides, such as CaB₆, SrB₆, BaB₆ and CeB₆, nitrides, such as TiN, SiN and BN, sulfides, such as Ln₂S₃ (where Ln is a rare earth element), oxynitrides, such as Ti—O—N and oxysulfides, such as Ti—O—S, which are known thermoelectric conversion materials.

### [Conductive Metal]

The conductive metal is preferably a precious metal that is difficult to be oxidized at high temperature, such as Pd, Ag, Pt or Au, and is more preferably Ag. The conductive metal differs from the thermoelectric conversion material mentioned above.

### [Layer Structure]

The thermoelectric conversion element is made of a sintered body containing a thermoelectric conversion material and a conductive metal, and usually has a multilayer structure including, for example, a first layer, a second layer, . . . , a Nth layer.

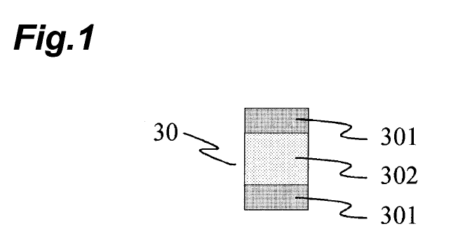

An example of a thermoelectric conversion element comprising three layers is shown in FIG. 1. The thermoelectric conversion element 30 shown in FIG. 1 comprises first layers 301 and a second layer 302. The first layers 301 are present on both ends of a sintered body containing a thermoelectric conversion material and a conductive metal. The second layer 302 is electrically connected to the first layers 301. The ratio (molar ratio) of the conductive metal relative to the total amount (moles) of the thermoelectric conversion material and the conductive metal in each first layer is larger than the ratio (molar ratio) of the conductive metal relative to the total amount (moles) of the thermoelectric conversion material and the conductive metal in the second layer. It is rpefereable that the ratio (molar ratio) of the conductive metal relative to the total amount (moles) of the thermoelectric conversion material and the conductive metal in the first layer be 0.1 or greater, more preferable that it be 0.1 or greater and 0.9 or smaller, and even more preferable that it be 0.3 or greater and 0.9 or smaller. If it is smaller than 0.1, it may become difficult to sufficiently lower the value of the resistance between the thermoelectric conversion material and the electrode, depending on the type of thermoelectric conversion materials, and if it is greater than 0.9, the thermal stress between the first layer and the second layer may be increased, depending on the type of thermoelectric conversion materials. A smaller ratio of the conductive metal in the second layer is preferred, and it may even contain no conductive metal. In order to increase the temperature difference between both ends of the thermoelectric conversion element, it is preferable that the proportion of the thickness of the second layer relative to the thickness of the first layer be at least 1, and is more preferable that it be at least 3.

The first layers 301 and second layer 302 are electrically connected by integration thereof with sintering. When the thermoelectric conversion element is used in a thermoelectric conversion module, the first layers 301 are electrically connected to electrodes.

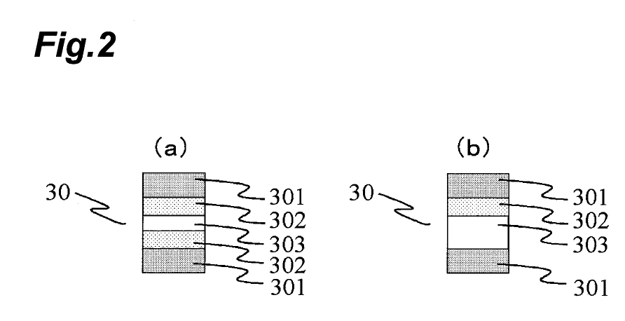

An example of a thermoelectric conversion element comprising five layers is shown in FIG. 2(a), and an example of a thermoelectric conversion element comprising four layers is shown in FIG. 2(b). The thermoelectric conversion elements 30 shown in FIGS. 2(a) and (b) comprise first layers 301, a second layer 302 and a third layer 303. The first layers 301 are present on both ends of a sintered body containing a thermoelectric conversion material and a conductive metal. The ratio (molar ratio) of the conductive metal relative to the total amount (moles) of the thermoelectric conversion material and the conductive metal in the first layer is larger than the ratio (molar ratio) of the conductive metal relative to the total amount (moles) of the thermoelectric conversion material and the conductive metal in the second layer. It is preferable that the ratio (molar ratio) of the conductive metal relative to the total amount (moles) of the thermoelectric conversion material and the conductive metal in the third layer be smaller than the ratio (molar ratio) of the conductive metal relative to the total amount (moles) of the thermoelectric conversion material and conductive metal in the second layer.

The second layer 302 is electrically connected to a first layer 301. The third layer 303 is electrically connected to the second layer 302.

The third layer may also be in contact with one of the two first layers, as shown in FIG. 2(b). The first layer 301, second layer 302 and third layer 303 are electrically connected by integration thereof with sintering. When these thermoelectric conversion elements are used in a thermoelectric conversion module, the first layers 301 are electrically connected to the electrodes.

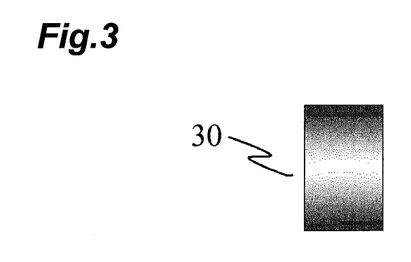

FIG. 3 shows an example of a thermoelectric conversion element (graded material) with an increased number of layers. The thermoelectric conversion element 30 shown in FIG. 3 is a graded material having a composition that changes in an essentially continuous manner. In FIG. 3, the increasing ratio of conductive metal is shown by darker color.

### [Method for Producing Thermoelectric Conversion Element]

The thermoelectric conversion element may be obtained by sintering a green body that can form a thermoelectric conversion element by sintering.

The green body, for example, (i) has a layer comprising a mixed powder of a thermoelectric conversion material and a conductive metal (the powder to form the first layer of the thermoelectric conversion element, hereunder referred to as “powder 1”), and a layer comprising a mixed powder of a thermoelectric conversion material and a conductive metal (the powder to form the second layer of the thermoelectric conversion element, hereunder referred to as “powder 2”), (ii) has a layer comprising a mixed powder of a thermoelectric conversion material and a conductive metal (powder 1) and a layer comprising a powder of a thermoelectric conversion material (powder 2), (iii) has a layer comprising a mixed powder of a thermoelectric conversion material and a conductive metal (powder 1), a layer comprising a mixed powder of a thermoelectric conversion material and a conductive metal (powder 2) and a layer comprising a mixed powder of a thermoelectric conversion material and a conductive metal (the powder to form the third layer, hereunder referred to as “powder 3”), or (iv) has a layer comprising a mixed powder of a thermoelectric conversion material and a conductive metal (powder 1), a layer comprising a mixed powder of a thermoelectric conversion material and a conductive metal (powder 2) and a layer comprising a powder of a thermoelectric conversion material (powder 3).

The thermoelectric conversion material can be prepared by calcining a starting material, and usually the starting material can be prepared by a method in which compounds respectively containing a metal element to compose the thermoelectric conversion material are weighted out so as to have a prescribed composition and then mixed. The thermoelectric conversion material may also be prepared by simultaneously mixing the starting material of the conductive metal therewith and then calcining the mixture.

A mixed powder of the thermoelectric conversion material and the conductive metal can be obtained by mixing the thermoelectric conversion material and the conductive metal. The mixing can be performed by either dry or wet method, and is preferably a method capable of mixing them as uniformly as possible. The apparatus thereof may be, for example, a ball mill, V-shaped mixer, vibrating mill, attritor, Dyno-Mill, Dynamic Mill, or the like.

For the molding it is sufficient to carry out a method that yields the prescribed shape, such as a board, a rectangular columnar or a circular columnar shape, and the molding may be accomplished, for example, by a method in which the powders (powder 1, powder 2, powder 3 or the like) are packed in a die and then pressed using an uniaxial press, cold isostatic press (CIP), mechanical press, hot press or hot isostatic press (HIP). When the thermoelectric conversion element has a first layer/second layer/first layer configuration (where “/” represents the interface), they are packed into the die in the stated order: powder 1/powder 2/powder 1. When it has a first layer/second layer/third layer/second layer/first layer configuration, they are packed into the die in the stated order: powder 1/powder 2/powder 3/powder 2/powder 1. When the number of layers is increased, the powder for each layer is packed into the die in order according to the layers which are to compose the thermoelectric conversion element. The green body may contain additives such as a binder, a dispersing agent and a release agent.

The sintering can usually be carried out under ordinary pressure. Also, molding and sintering may be carried out simultaneously using a hot press or pulse electrification sintering method. The sintered body may have a board-like, rectangular columnar, circular columnar or spherical shape, and it is preferable that it have a columnar shape, such as circular columnar or rectangular columnar.

The thermoelectric conversion element is highly useful as a thermoelectric conversion element for a thermoelectric conversion module. Since using the thermoelectric conversion element can reduce the contact resistance described hereunder on one or both ends thereof, it can lower resistance between the electrode and the thermoelectric conversion element in a thermoelectric conversion module, thus allowing the thermoelectric conversion module output to be increased.

### Electrodes

The electrode is made of a material that is difficult to be oxidized in the environment in which the thermoelectric conversion module is to be used, and can be made of a metal such as Pd, Ag, Pt or Au. Shapes and sizes of the electrode can be appropriately selected according to the shapes, sizes and outputs of the thermoelectric conversion modules.

### Other Components

The substrate is a member for integration of a plurality of thermoelectric conversion elements and a plurality of electrodes as a thermoelectric conversion module, and has the necessary mechanical strength. The substrate will usually be in the form of a board.

The support is a member for fixing the thermoelectric conversion elements to the substrate or electrodes, and has a shape of one suitable for fixation such as a cap shape. The support is usually made of an electrical insulation member.

The spring is a member disposed between, for example, the substrate and the electrode for alleviation of thermal stress to the thermoelectric conversion element.

Method for producing thermoelectric conversion module The thermoelectric conversion module comprises the thermoelectric conversion element and the electrode, and normally comprises a plurality of the thermoelectric conversion elements and a plurality of the electrodes. The thermoelectric conversion module is usually produced by assembling the thermoelectric conversion elements (p-type thermoelectric conversion elements, n-type thermoelectric conversion elements), electrodes and, if necessary, the substrate or the support.

In production of the thermoelectric conversion module, (a) each p-type thermoelectric conversion element is electrically connected to an electrode via one face without a joint and is electrically connected to another electrode via the other face with a joint, or (b) each p-type thermoelectric conversion element is electrically connected to an electrode via one face without a joint and is electrically connected to another electrode via the other face without a joint.

As regards an n-type thermoelectric conversion element, similar to a p-type thermoelectric conversion element, (a) each n-type thermoelectric conversion element is electrically connected to an electrode via one face without a joint and is electrically connected to another electrode via the other face with a joint, or (b) each n-type thermoelectric conversion element is electrically connected to an electrode via one face without a joint and is electrically connected to another electrode via the other face without a joint.

Throughout the present specification, “without a joint” means that no jointing material (solder) is used, and “with a joint” means that a jointing material (solder) is used.

An embodiment of a thermoelectric conversion module will now be explained with reference to the accompanying drawings.

Throughout the explanation of the drawings, the same reference numerals will be put on the same or corresponding elements and overlapping explanations will be omitted. Also, the dimensional proportions in the drawings do not necessarily match the actual dimensional proportions.

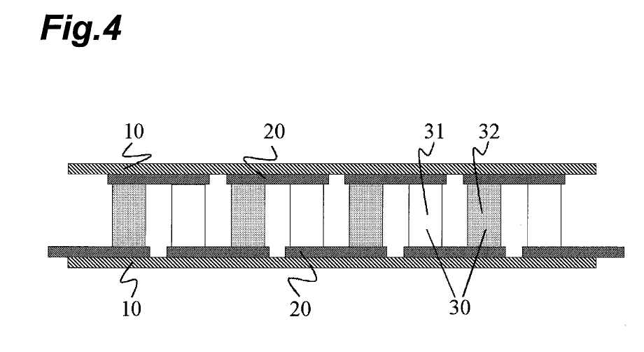

FIG. 4 is a schematic cross-sectional view showing an embodiment of a thermoelectric conversion module. The thermoelectric conversion module shown in FIG. 4 has a plurality of p-type thermoelectric conversion elements 31 and n-type thermoelectric conversion elements 32 alternately disposed between two opposing substrates 10 which are above and below. The p-type thermoelectric conversion elements and n-type thermoelectric conversion elements are each made of a sintered body containing a thermoelectric conversion material and a conductive metal. The p-type thermoelectric conversion elements 31 and n-type thermoelectric conversion elements 32 are electrically connected in series via a plurality of electrodes 20 attached to the two opposing substrates above and below, the thermoelectric conversion elements and electrodes are electrically connected without joints. It is sufficient if at least one of the locations where the thermoelectric conversion elements and electrodes are electrically connected are electrically connected without a joint.

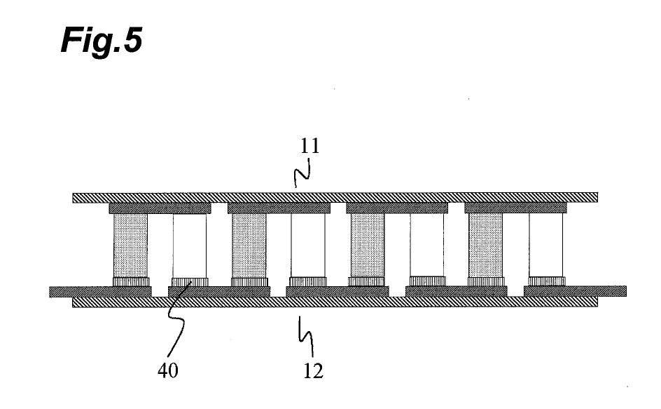

FIG. 5 is a schematic cross-sectional view showing another embodiment of a thermoelectric conversion module. The distinguishing feature from the thermoelectric conversion module of FIG. 4 is that the thermoelectric conversion elements 30 and electrodes 20 at the lower-temperature side 12 of the thermoelectric conversion module are electrically connected using a jointing material (solder) 40. As shown in FIG. 5, the thermoelectric conversion elements 30 and electrodes 20 need be electrically connected without a joint only at the higher-temperature side 11 of the thermoelectric conversion module, and the thermoelectric conversion elements and electrodes may be electrically connected with a joint (using a jointing material) at the lower-temperature side 12 which has relatively low thermal stress.

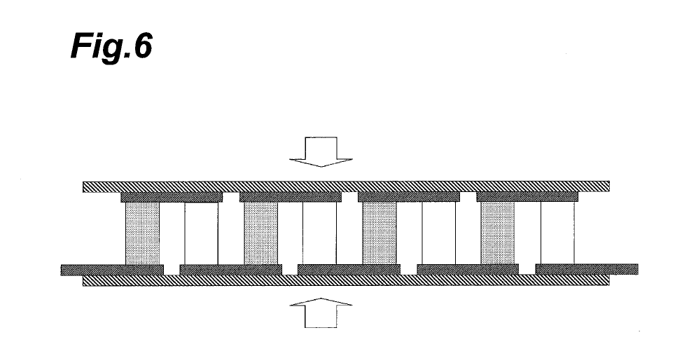

Also, as shown in FIG. 6, the thermoelectric conversion module is usually used in a state under vertical pressure against two substrates. For example, it may be used with application of pressure by screwing the two substrates together.

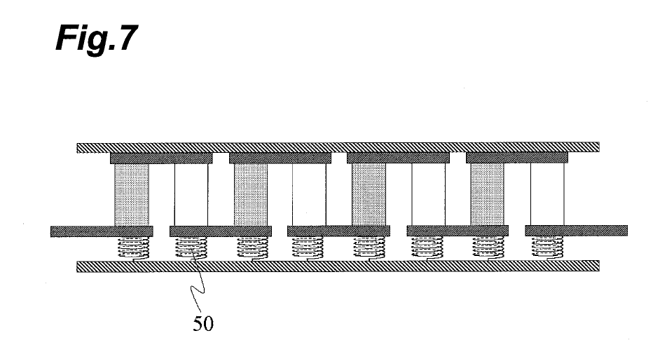

FIG. 7 is a schematic cross-sectional view showing another embodiment of a thermoelectric conversion module. The distinguishing feature from the thermoelectric conversion module of FIG. 4 is that springs 50 exist between the electrodes and a substrate. As shown in FIG. 7, the presence of the springs 50 lying between the electrodes and substrate can inhibit the effects of deformation of the thermoelectric conversion element under thermal expansion. It is preferable that the springs be disposed on at least the lower-temperature side of the thermoelectric conversion module.

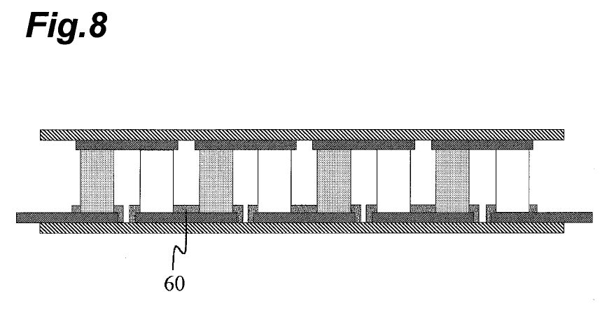

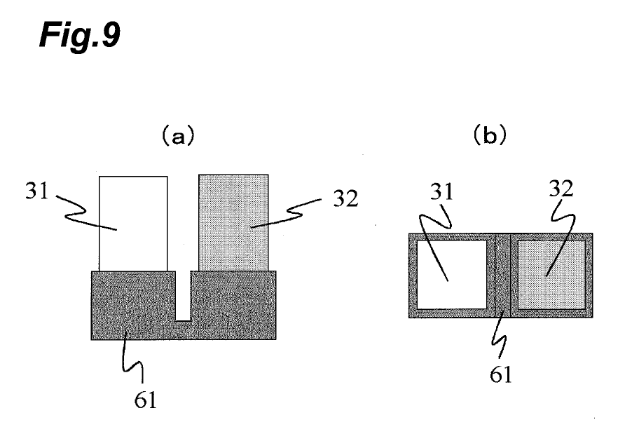

FIG. 8 is a schematic cross-sectional view showing another embodiment of a thermoelectric conversion module. The distinguishing feature from the thermoelectric conversion module of FIG. 4 is that the thermoelectric conversion element is supported by an element support 60. It is preferable that the element support be made of an electrical insulation member. The shape of the element support may be, for example, a cap shape. FIG. 9(a) and FIG. 9(b) schematically show modes of use of the cap-shaped element support 61. In FIG. 9, (a) is a view from the side, and (b) is a view from the top. The cap-shaped element support need only have an electrode in the center, and if the module design allows, it may itself be the electrode.

### EXAMPLES

The invention will now be explained in detail by examples. The following methods were used for evaluation of the sintered body structure, contact resistance and thermoelectric conversion material properties.

### 1. Structural Analysis

The crystal structures of the sintered body test samples were determined by powder X-ray diffraction using a model RINT2500TTR X-ray diffraction measuring apparatus by Rigaku Corp., with CuKα as the radiation source.

2. Contact resistance

A platinum wire was mounted on a columnar sintered body test sample with paste, the resistance value R_{A} (Ω) was determined by the direct current four-terminal method and the resistance value R_{B} (Ω) by the direct current two-terminal method, and the contact resistance (Ω) was calculated by the formula shown below. The areas of the electrodes in contact with the test sample were made equal for measurement by the direct current two-terminal method.

Contact resistance=(R_{B}−R_{A})/2

### Comparative Example 1

### Thermoelectric Conversion Material (CaMn_{0.98}Mo_{0.02}O₃+CuO)

After weighing out:

8.577 g of CaCO₃ (trade name: CS3N-A, by Ube Material Industries, Ltd.),
7.852 g of MnO₂ (product of Kojundo Chemical Lab. Co., Ltd.),
0.247 g of MoO₃ (product of Kojundo Chemical Lab. Co., Ltd.), and
0.359 g of CuO (product of Kojundo Chemical Lab. Co., Ltd.),
they were mixed for 20 hours with a wet ball mill (medium: zirconia ball) to obtain a mixture. The mixture was held in air at 900° C. for 10 hours to be calcined, obtaining a calcined product thereby. The calcined product was pulverized for 20 hours with a wet ball mill (medium: zirconia ball) and then molded with a uniaxial press (molding pressure: 500 kg/cm²) to obtain a columnar green body. The green body was held in air at 1050° C. for 10 hours to be sintered, obtaining sintered body 1 thereby. Sintered body 1 had the same type of crystal structure as perovskite-type crystals of CaMnO₃. The contact resistance of sintered body 1 was converted to 100.

Sintered body 1 having a length of 10 mm in the direction of temperature difference was used as a thermoelectric conversion element, and sintered body 1 was electrically connected to the electrode using an Ag plate as the electrode and silver paste as the jointing material at 800° C. to fabricate an element-electrode link (module). The element-electrode resistance in the module was 0.1Ω. A thermal cycle was performed from room temperature to 700° C. repeatedly while applying a pressure of 2 Kg/cm² to the module. The element-electrode resistance increased to 5Ω after 3 cycles had been completed.

Ag plates (2 plates in total) were without using a jointing material, attached to both ends of sintered body 1 and the element-electrode resistance was measured while applying a pressure of 2 kg/cm². The resistance was a very high value of 16Ω, and the module was therefore unsuitable for use as a thermoelectric conversion module.

### Example 1

### First Layer: 70% by Mole Thermoelectric Conversion Material (CaMn_{0.98}Mo_{0.02}O₃+CuO)+30% by Mole Conductive Metal (Ag); Second Layer: 100% by Mole Thermoelectric Conversion Material (CaMn_{0.98}Mo_{0.02}O₃+CuO)

After weighing out:

8.577 g of CaCO₃ (trade name: CS3N-A, by Ube Material Industries, Ltd.),
7.852 g of MnO₂ (product of Kojundo Chemical Lab. Co., Ltd.),
0.247 g of MoO₃ (product of Kojundo Chemical Lab. Co., Ltd.),
0.359 g of CuO (product of Kojundo Chemical Lab. Co., Ltd.), and
4.482 g of Ag₂O (product of Kojundo Chemical Lab. Co., Ltd.),
they were mixed for 20 hours with a wet ball mill (medium: zirconia ball) and held in air at 900° C. for 10 hours to be calcined, obtaining a calcined product thereby. The calcined product was pulverized for 20 hours with a wet ball mill (medium: zirconia ball) to obtain powder 1 (powder for formation of the first layer). Powder 1 had the same type of crystal structure as perovskite-type crystals of CaMnO₃. An Ag crystal structure peak was detected in powder 1.

After weighing out:

8.577 g of CaCO₃ (trade name: CS3N-A, by Ube Material Industries, Ltd.),
7.852 g of MnO₂ (product of Kojundo Chemical Lab. Co., Ltd.),
0.247 g of MoO₃ (product of Kojundo Chemical Lab. Co., Ltd.), and
0.359 g of CuO (Kojundo Chemical Lab. Co., Ltd.), they were mixed for 20 hours with a wet ball mill (medium: zirconia ball) and held in air at 900° C. for 10 hours for to be calcined, obtaining a calcined product thereof. The calcined product was pulverized for 20 hours with a wet ball mill (medium: zirconia ball) to obtain powder 2 (powder for formation of the second layer). Powder 2 had the same type of crystal structure as perovskite-type crystals of CaMnO₃.

Powder 1 and powder 2 were packed into a die so as to have a weight ratio of powder 1:powder 2:powder 1=1:18:1, and molded using an uniaxial press (molding pressure: 500 kg/cm²), to obtain a columnar green body. The green body was held in air at 1050° C. for 10 hours to be sintered, obtaining sintered body 2 that has the structure first of layer/second layer/first layer. Sintered body 2 had a contact resistance of 5, which was extremely low relative to sintered body 1. Because of the extremely low contact resistance, sintered body 2 is suitable as a thermoelectric conversion element in a thermoelectric conversion module in which the thermoelectric conversion elements and electrodes are electrically connected without joints.

Ag plates (2 plates in total) were, without a joint, attached to both ends of sintered body 2 and the element-electrode link was formed by applying a pressure of 2 kg/cm². The element-electrode resistance in the link was 0.1Ω. A thermal cycle of the link was performed repeatedly in the same manner as Comparative Example 1. No change in element-electrode resistance was seen even after completion of 5 cycles.

### Example 2

### First Layer: 80% by Mole Thermoelectric Conversion Material (CaMn_{0.98}Mo_{0.02}O₃+CuO)+20% by Mole Conductive Metal (Ag); Second Layer: 100 Mol % Thermoelectric Conversion Material (CaMn_{0.98}MO_{0.02}O₃+CuO)

Sintered body 3 was fabricated in the same manner as Example 1, except that the amount of Ag₂O for production of powder 1 was changed to 2.614 g. Sintered body 3 had a contact resistance of 25, which was low relative to sintered body 1. Because of the low contact resistance, sintered body 3 is suitable as a thermoelectric conversion element in a thermoelectric conversion module in which the thermoelectric conversion elements and electrodes are electrically connected without joints.

Ag plates (2 plates in total) were, without a joint, attached to both ends of sintered body 3 and the element-electrode link was formed by applying a pressure of 2 kg/cm². The element-electrode resistance in the link was 0.2Ω. A thermal cycle of the link was performed repeatedly in the same manner as Comparative Example 1. No change in element-electrode resistance was seen even after completion of 5 cycles.

### INDUSTRIAL APPLICABILITY

According to the invention there is provided a thermoelectric conversion module that can suppress thermal stress between a thermoelectric conversion element and an electrode, and a thermoelectric conversion element favorable for the module. The thermoelectric conversion module is highly favorable for medium and high temperature use, and can be favorably used for thermoelectric conversion power generation utilizing factory waste heat or incinerator waste heat, industrial furnace waste heat, automobile waste heat, ground heat, solar heat or the like, and in precision temperature control devices such as laser diodes, as well as air conditioners, refrigerators and the like, whereby breakdown of thermoelectric conversion modules caused by thermal stress can be reduced and usable life can be extended.

1. A thermoelectric conversion module comprising a plurality of thermoelectric conversion elements and a plurality of electrodes, wherein each of the thermoelectric conversion elements is made of a sintered body containing a thermoelectric conversion material and a conductive metal, has two faces, and satisfies the following condition (a) or (b):
(a) each thermoelectric conversion element is electrically connected to an electrode via one face without a joint, and is electrically connected to another electrode via the other face with a joint;
(b) each thermoelectric conversion element is electrically connected to an electrode via one face without a joint, and is electrically connected to another electrode via the other face without a joint.

2. The module according to claim 1, wherein the sintered body is a multilayer body comprising a first layer and a second layer, wherein the first layer is electrically connected to an electrode without a joint and contains a thermoelectric conversion material and a conductive metal, the second layer is electrically connected to the first layer with a joint and contains a thermoelectric conversion material and a conductive metal, and the molar ratio of the conductive metal relative to the total molar amount of the thermoelectric conversion material and the conductive metal in the first layer is larger than the molar ratio of the conductive metal relative to the total molar amount of the thermoelectric conversion material and the conductive metal in the second layer.

3. The module according to claim 1, wherein the sintered body has a columnar shape.

4. The module according to claim 1, wherein the conductive metal is Ag.

5. The module according to claim 1, wherein the thermoelectric conversion material is an oxide.

6. The module according to claim 5, wherein the oxide has a perovskite-type crystal structure or a layered perovskite-type crystal structure.

7. The module according to claim 1, wherein the oxide contains manganese.

8. The module according to claim 7, wherein the oxide further contains calcium.

9. The module according to claim 2, wherein the molar ratio of the conductive metal relative to the total molar amount of the thermoelectric conversion material and conductive metal in the first layer is 0.1 or greater.

10. The module according to claim 1, wherein the sintered body further contains copper oxide.

11. A thermoelectric conversion element comprising a multilayer sintered body that comprises a first layer and a second layer, wherein the first layer is present on one end of the sintered body and contains a thermoelectric conversion material and a conductive metal, the second layer is electrically connected to the first layer with a joint and contains a thermoelectric conversion material and a conductive metal; and
the molar ratio of the conductive metal relative to the total molar amount of the thermoelectric conversion material and the conductive metal in the first layer is larger than the molar ratio of the conductive metal relative to the total molar amount of the thermoelectric conversion material and the conductive metal in the second layer.

12. The element according to claim 11, wherein the sintered body has a columnar shape.

13. The element according to claim 11, wherein the conductive metal is Ag.

14. The element according to claim 11, wherein the thermoelectric conversion material is an oxide.

15. The element according to claim 14, wherein the oxide has a perovskite-type crystal structure or a layered perovskite-type crystal structure.

16. The element according to claim 11, wherein the oxide contains manganese.

17. The element according to claim 16, wherein the oxide further contains calcium.

18. The element according to claim 11, wherein the molar ratio of the conductive metal relative to the total molar amount of the thermoelectric conversion material and the conductive metal in the first layer is 0.1 or greater.

19. The element according to claim 11, wherein the sintered body further contains copper oxide.
